(19) United States
(12) Patent Application Publication
(10) Pub. No.: US 2026/0086180 A1
(43) Pub. Date: Mar. 26, 2026

(54) Ascertaining Excitation Pulses for Simultaneous Recording of at Least Two Parallel Slices During a Magnetic Resonance Tomography Measurement

(71) Applicant: Siemens Healthineers AG, Forchheim (DE)

(72) Inventors: Dominik Paul, Bubenreuth (DE); Flavio Carinci, Wurzburg (DE); Mario Zeller, Erlangen (DE)

(73) Assignee: Siemens Healthineers AG, Forchheim (DE)

(21) Appl. No.: 19/335,146

(22) Filed: Sep. 22, 2025

(30) Foreign Application Priority Data
Sep. 23, 2024 (DE) 10 2024 209 090.5

(51) Int. Cl. G01R 33/483; G01R 33/561; G01R 33/565

(52) U.S. Cl. CPC G01R 33/4835; G01R 33/5611; G01R 33/56572

(57) ABSTRACT

Techniques are described for ascertaining excitation pulses for simultaneous recording parallel slices during a magnetic resonance tomography measurement with a magnetic resonance tomography system. A target position is defined for each of the at least two parallel slices, determining theoretical gradient values at the target positions assuming an ideal (e.g. linear), local gradient profile, and actual gradient values are determined at the target positions based on a predetermined, location-dependent, real gradient value distribution. A frequency offset is determined for each of the parallel slices based on a difference between the actual gradient value and the theoretical gradient value, as well as a pulse frequency of an excitation pulse to be applied as a superposition of individual pulses of the parallel slices, with the frequency of the individual pulses being based on the frequency offset and the theoretical gradient value of the respective parallel slices.

### CROSS-REFERENCE TO RELATED APPLICATIONS

The present application claims priority to and the benefit of Germany patent application no. DE 10 2024 209 090.5, filed on Sep. 23, 2024, the contents of which are incorporated herein by reference in their entirety.

### TECHNICAL FIELD

The disclosure relates to a computer-implemented method for ascertaining excitation pulses for simultaneous recording of at least two parallel slices during a magnetic resonance tomography measurement, a method for the simultaneous recording of at least two parallel slices in a magnetic resonance tomography measurement, a corresponding computer program product, and a magnetic resonance tomography system.

### BACKGROUND

Magnetic resonance systems (MR systems) have a gradient system for spatial encoding of the MR signal. Spatial encoding is typically based on linear courses of the gradient fields of the gradient system. However, due to design compromises which are usually necessary or expedient, as a rule gradient systems exhibit a certain degree of non-linearity, in particular at the edge areas of the image area of the respective MR scanner. Due to this non-linearity of the gradient system, slices are excited in a manner that is not true to the location, so that the actual slice position does not correspond exactly to the desired slice position.

When exciting a plurality of slices simultaneously, the slices are excited with an individual pulse that is a combination of two or more individual pulses that have a shift in their frequency between them. This kind of MR imaging is also referred to as SMS (Simultaneous Multi-Slice) imaging. Based on the assumption of a linear gradient course Gz, the frequency f(z) of the individual pulses for exciting a slice at the position z can be calculated by means of f(z)=2π×γ (B00+Gz×z), with the gyromagnetic ratio γ, also referred to as the Larmor constant, and an offset of the magnetic field density B00. In this application, for the sake of simplicity, the offset is set to zero in some examples, so that the frequency can be described as f(z)=m×Gz×z, where m is a prefactor comprising the gyromagnetic ratio γ (Larmor constant). The individual pulses thus exhibit a shift in their frequency which is in proportion to Gz.

The actual non-linearity in Gz now means that the slices actually recorded do not correspond exactly to the desired slices.

Conventionally, there are approaches for mathematically correcting distortion caused by the non-linearity of the gradient course whereby the distortion is corrected based on the actual gradient field. One method for correcting distortion is described in U.S. Pat. No. 8,054,079, for example. This can be used to correct distortion within a slice. However, the problem with regard to the recorded slices not being recorded at the desired slice positions cannot be remedied. Discrepancies may arise whereby the slices recorded do not show the anatomy which was expected during planning.

### SUMMARY

It is therefore an object of the present disclosure to provide a possibility by which the above-mentioned problems can be at least partially remedied. In particular, it is desirable to provide a possibility by which parallel slices can be recorded with improved accuracy.

This object is achieved by the various embodiments as described herein, including the claims, the description, and the associated Figures.

According to a first aspect of the disclosure, a computer-implemented method for ascertaining excitation pulses for the simultaneous recording of at least two parallel slices during a magnetic resonance tomography measurement (MR measurement) with a magnetic resonance tomography system (MR system) is provided. The method comprises the following steps:
defining a target position for each of the at least two parallel slices;
determining theoretical gradient values at the target positions, assuming an ideal, e.g. linear, local gradient profile;
determining actual gradient values at the target positions based on a predetermined, location-dependent, real gradient value distribution;
calculating the gradient value differences between the theoretical gradient value and the actual gradient value of the individual slices;
determining a frequency offset for each of the parallel slices based on a difference between the actual gradient value and the theoretical gradient value;
determining a pulse frequency of an excitation pulse to be applied as a superposition of individual pulses of the parallel slices, the frequency of the individual pulses being based on the frequency offset and the theoretical gradient value of the respective parallel slices.

Advantageously, the method according to the disclosure also enables slices in edge areas of the image area of the MR scanner to be placed with improved precision. For example, an entire anatomy can be recorded with improved accuracy, regardless of the location and position. In an embodiment, it is possible to compensate for shifts due to distortion of the gradient system. The method can be carried out as a computer-implemented method, e.g. automatically by a computer unit. For example, the method can be carried out by a control unit of the MR system. For the smooth operation of the MR scanner, it is advantageous if a frequency offset is determined for each of the parallel slices instead of completely recalculating the frequency. In this manner, an existing imaging sequence can be used for the MR measurement, the excitation pulses likewise being calculated normally based on the target position of the parallel slices. Before the excitation pulses are played out, they are simply corrected with the frequency offsets calculated according to the disclosure. The method is intended for a multi-slice (also multiband) excitation pulse, with which at least two slices are excited simultaneously. In various embodiments, any suitable number of slices, e.g. 2 to 4 slices, are excited simultaneously. However, the method can generally also be carried out for individual excitation pulses.

According to the disclosure, a target position of the at least two parallel slices is first defined. The at least one target position can, for example, be entered by a user. The target position can be defined according to the user input. The target position can be selected or defined, for example, based on a pre-scan. The target position can be defined as a position on an axis perpendicular to the respective slice and/or as a position on the z-axis of the MR system. The z-axis of the MR system is typically parallel to a longitudinal axis of an MR tunnel of the MR system. However, it can also have any other orientation, e.g. it can also not be parallel to an axis of the MR system. For example, with two slices, two slice positions A and B can be defined.

Based on the defined target positions, theoretical gradient values are determined assuming an ideal, e.g. linear, local gradient profile. For example, for the slice positions A and B, the theoretical gradient values g_{z,t}(A), g_{z,t}(B) can be determined based on a gradient G_{z} of the gradient course according to equations of the form g_{z,t}(A)=G_{z}×A and g_{z,t}(B)=G_{z}×B. In addition, actual gradient values are determined. Actual gradient values are e.g. defined in that they are closer to the real gradient values of the MR system than the theoretical gradient values and/or essentially correspond to the real gradient values of the MR system. The determination of the actual gradient values is based on a predetermined, location-dependent, real gradient value distribution. Such a real gradient value distribution is usually already known and stored in MR systems. It is used, for example, for subsequent distortion correction during image reconstruction.

Advantageously, an already existing gradient value distribution can thus be used, for example. A frequency offset is further determined based on the theoretical and the actual gradient values. For example, the determination of the frequency offset can be based on a difference between the respective theoretical gradient value and the actual gradient value. For example, the frequency offsets df(A) and df(B) can be determined for two slices at the positions A and B. With the help of the frequency offsets, e.g. based on the theoretical gradient value, the individual pulses for the slices can be determined. For example, according to the theoretical gradient values for two slices, frequencies of fₜ(A)=m×G_{z}×A and fₜ(B)=m×G_{z}×B can result, m being a constant prefactor comprising the Larmor constant. The individual pulses can be determined for instance by adding or subtracting the respective frequency offset. According to the example of two slices, the frequencies of the individual pulses can be determined, for example, with f_{E}(A)=fₜ(A)+df(A) and f_{E}(B)=fₜ(B)+df(B). The excitation pulse is determined as a superposition of the individual pulses of the parallel slices. For example, the excitation pulse can be determined according to f_{A}=f_{E}(A)+f_{E}(B). The excitation pulse can thus be derived or composed directly from the individual pulses.

According to one embodiment, the frequency offsets are specified by determining a distorted slice position in each case based on the respective actual gradient value and the respective theoretical gradient value of the respective slice and determining the respective frequency offset based on the distorted slice position. In an embodiment, the distorted slice position is in each case the actual slice position which results from the use of one of the theoretical gradient values. As a result of the gradient course not being perfectly linear in reality, assuming theoretical, linear gradient values results in slice positions which deviate from the target positions. These are referred to as distorted slice positions in the context of the disclosure. For example, the frequency offset can be determined by calculating the distance between the respective target position and the distorted slice position. If, for example, the distance is dA for a target position A and dB for a target position B, the frequency can be calculated as, for example, df(A)=m×G_{z}×dA or df(B)=m×G_{z}×dB, respectively. The distorted slice position can be determined, for example, by equating a formula for the theoretical gradient value (at the target position) and for the actual gradient value (at the distorted slice position) and solving for the distorted slice position.

According to one embodiment, the frequency offsets are specified by determining a distorted slice position based on the inverse application of a distortion correction to the target position and determining the respective frequency offset based on the distorted slice position. Methods for correcting distortion are known in the prior art. For example, a method for correcting distortion is described in U.S. Pat. No. 8,054,079. Advantageously, a known method or a known formula can thus be used to determine the distorted slice position. For example, the target positions can be placed in a virtual image matrix which is orthogonal to the stack of parallel slices and processed by the Inverse Function of the distortion correction.

According to one embodiment, the distorted slice positions are viewed along a theoretical slice plane, defined based on a center point or a center line or based on a central position of the respective slices distorted according to the actual gradient value. The center point or the center line may correspond to an averaged position of the respective slice or define an averaged position. The central position is, for example, the point of the slice which is located centrally in the scan area or located most centrally in the scan area. In addition to a displacement of the slices along the z-axis, distortions of the slices themselves may also occur. This embodiment provides a solution for dealing with this. Typically, the most important data of an image is arranged centrally in the real image space. Concentrating on a central position thus ensures that the most important data is captured in the best possible position. The determination of an averaged position of the slices can be another means of counteracting distortion of the slices themselves. In an embodiment, this can ensure that all data of the respective slice can be recorded with relatively accurate positioning.

According to one embodiment, the frequency offsets are determined by calculating the gradient value difference between the theoretical gradient value and the actual gradient value of the individual slices and determining the respective frequency offsets based on the respective gradient value difference of the respective slice. For example, with a difference Δg_{z}=g_{z,p}(A)−g_{z,t}(A) between the respective theoretical gradient g_{z,t}(A) and actual gradient g_{z,p}(A) at the target position A, the frequency offset df(A)=m×Δg_{z}×A can be determined. From this, the respective individual pulse can in turn be determined, for example, in the form f_{E}(A)=m×(g_{z,t}(A)×A+Δg_{z}×A). This embodiment may represent a particularly simple means of determining the frequency offsets or the individual pulses.

According to one embodiment, the frequency of the individual pulses is determined by adding a frequency based on the respective theoretical gradient value and the frequency offset. For example, the individual pulses f_{E}(A) and f_{E}(B) for two target positions A and B of two slices with the frequency offsets df(A) and df(B) can be determined in the form f_{E}(A)=m×g_{z,t}(A)×A+df(A) or f_{E}(B)=m×g_{z,t}(B)×B+df(B). This embodiment can be a particularly effective means of determining the frequency of the individual pulses.

According to one embodiment, the actual gradient values are taken from a gradient field map or a function, e.g. comprising a spherical harmonic, which describes the gradient field map. In an embodiment, the gradient field map can be a map or a list which specifies real gradient values depending on the location. For instance, the function or spherical harmonic can be a parameterized function. As gradient values do not usually change abruptly based on the location, the real gradient values can also be described well by a function. A spherical harmonic can be a particularly efficient means of describing the gradient values depending on the location. In an embodiment, real gradient values can be approximated with great accuracy using a spherical harmonic. As typical gradient systems are usually rotationally symmetric, they can be represented particularly well by a spherical harmonic. For example, the function can be used to determine the gradient field at a point P (x, y, z). Alternatively, however, other types of functions can also be used. For example, the gradient field map can be determined by measuring the actual gradient field strength at specific locations. The gradient field map can be approximated by parameterization of a function, e.g. a spherical harmonic. Advantageously, with a parameterized function, not all explicit values of the gradient field map have to be stored. The spherical harmonic can, for example, comprise normalized coefficients. For simplification, small coefficients which do not make a significant contribution can be ignored. Normalization can take the following form, for example,

$$norm ( n , m ) = {( - 1 )}^{m} \sqrt{\frac{( 2 n + 1 ) ( n - m ) !}{2 ( m + n )}}$$

$$where$$

$$norm ( n , 0 ) = 1$$

From the spherical harmonic, the field or its z-component can be calculated, for example, based on equations of the form:

$${B}_{z} ( r , θ , ϕ ) = {G}_{x} {r}_{0} {\sum }_{n} {\sum }_{m} A ( n , m ) norm ( n , m ) {( \frac{r}{{r}_{0}} )}^{n} cos ( m ϕ ) {P}_{n}^{m} ( cos ( θ ) )$$

### for the X-gradient,

$${B}_{z} ( r , θ , ϕ ) = {G}_{y} {r}_{0} {\sum }_{n} {\sum }_{m} B ( n , m ) norm ( n , m ) {( \frac{r}{{r}_{0}} )}^{n} sin ( m ϕ ) {P}_{n}^{m} ( cos ( θ ) )$$

### for the Y-gradient, and

$${B}_{z} ( r , θ , ϕ ) = {G}_{z} {r}_{0} {\sum }_{n} A ( n , 0 ) {( \frac{r}{{r}_{0}} )}^{n} sin ( m ϕ ) {P}_{n}^{0} ( cos ( θ ) )$$

for the Z-gradient, where

$${P}_{n}^{m} ( cos ( θ )$$

is a Legendre polynomial which is defined as:

$${P}_{n}^{m} ( x ) = {( - 1 )}^{m} {( 1 - {x}^{2} )}^{m / 2} {d}^{m} [ {P}_{n} ( x ) ] / {dx}^{m}$$

the Legendre polynomial satisfying the differential equation:

$$( 1 - {x}^{2} ) {y}^{″} - 2 {xy}^{′} + n ( n + 1 ) y = 0$$

The expressions for X and Z can be used, for example, for Z-gradients without rotational symmetry.

A further aspect of the disclosure is a method for the simultaneous recording of at least two parallel slices in a magnetic resonance tomography measurement with a magnetic resonance tomography system, the method comprising the following steps:
applying a method for ascertaining excitation pulses for simultaneous recording of at least two parallel slices during a magnetic resonance tomography measurement as described herein;
performing the magnetic resonance tomography measurement with the determined excitation pulses.

All advantages and features of the method for ascertaining excitation pulses for simultaneous recording of at least two parallel slices during a magnetic resonance tomography measurement can be transferred analogously to the method for the simultaneous recording of at least two parallel slices in a magnetic resonance tomography measurement and vice versa. In an embodiment, the magnetic resonance tomography measurement can be based on the recording of at least two parallel slices. For instance, the magnetic resonance tomography measurement can be based on a simultaneous multi-slice method (SMS method).

A further aspect of the disclosure is a computer program product or computer-readable storage medium, comprising commands which, when carried out by a computer, e.g. a control apparatus of a magnetic resonance tomography system, prompt the computer to carry out the steps of any of the methods as described herein. All advantages and features of the methods described herein can be transferred analogously to the computer program product and vice versa. The computer program product can, for example, be stored on a computer-readable storage medium, e.g. a non-volatile storage medium. The storage medium can be, for example, a hard disk, an SSD, flash memory, an online server, etc.

A further aspect of the disclosure is a magnetic resonance tomography system which is designed to record at least two parallel slices simultaneously during a magnetic resonance tomography measurement, comprising a control apparatus with a computer program product as described herein. In an embodiment, the control apparatus is designed to control the measurement operation of the magnetic resonance tomography system. All advantages and features of the methods and the computer program product described herein can be transferred analogously to the magnetic resonance tomography system and vice versa.

All embodiments described herein can be combined with one another, unless explicitly stated otherwise.

### BRIEF DESCRIPTION OF THE DRAWINGS

Embodiments are described hereinafter with reference to the associated figures.

FIG. 1 illustrates a flow chart of an example method for ascertaining excitation pulses for the simultaneous recording of at least two parallel slices during a magnetic resonance tomography measurement with a magnetic resonance tomography system, according to an embodiment of the disclosure;

FIG. 2 illustrates a flow chart of another example method for the simultaneous recording of at least two parallel slices during a magnetic resonance tomography measurement with a magnetic resonance tomography system, according to an embodiment of the disclosure;

FIG. 3 illustrates an example ideal gradient course, which is linear, compared with an exemplary real gradient course, which deviates from a linear course, according to an embodiment of the disclosure;

FIG. 4 illustrates an example cross-sectional image of a part of the body with target positions for a plurality of slices, according to an embodiment of the disclosure;

FIG. 5 illustrates an example cross-sectional image of a part of the body with distorted slice positions for a plurality of slices, according to an embodiment of the disclosure;

FIG. 6 illustrates schematically an example target position and an example distorted slice position for two slices respectively, according to an embodiment of the disclosure;

FIG. 7 illustrates schematically an example target position and an example distorted slice position for two slices respectively, a center line of a distorted slice position being plotted, according to an embodiment of the disclosure; and

FIG. 8 illustrates a section of an example magnetic resonance tomography system, according to an embodiment of the disclosure.

### DETAILED DESCRIPTION OF THE DISCLOSURE

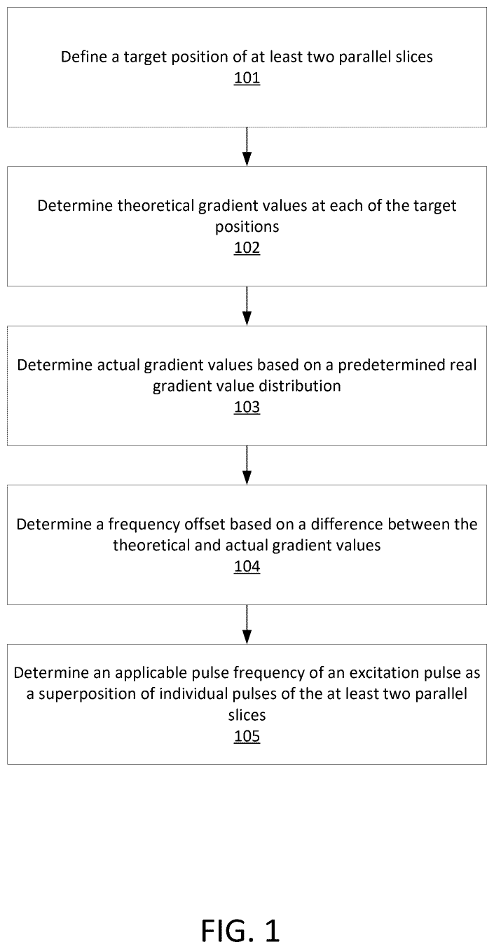

FIG. 1 illustrates a flow chart of an example method for ascertaining excitation pulses for the simultaneous recording of at least two parallel slices during a magnetic resonance tomography measurement with a magnetic resonance tomography system, according to an embodiment of the disclosure. In this example, FIG. 1 shows a flow chart of a computer-implemented method for ascertaining excitation pulses for simultaneous recording of at least two parallel slices during a magnetic resonance tomography measurement with a magnetic resonance tomography system 4 according to an embodiment of the disclosure.

In a first step 101, a target position 22 of each of the at least two parallel slices is defined. In two parallel slices, two target positions 22 can be defined accordingly. If a plurality of images of parallel slices are to be recorded successively, a plurality of sets of target positions 22 can be defined accordingly and the method can be carried out for all sets of target positions 22. In a further step 102, theoretical gradient values are determined at each of the target positions 22, an ideal, for instance linear, gradient course 11 being assumed. In a further step 103, actual gradient values are determined at the target positions 22. The determination of the actual gradient values in this step 103 is based on a predetermined real gradient value distribution. For example, the actual gradient values can be taken from a gradient field map or a function which describes the gradient field map. For example, the function may be a spherical harmonic or may include a spherical harmonic.

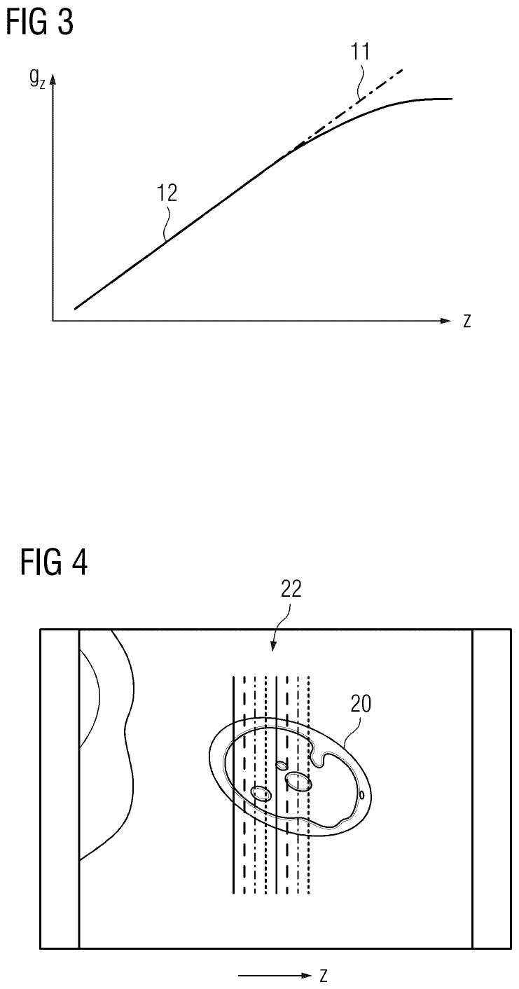

FIG. 3 shows an example of an ideal gradient course 11, which is linear, compared with an (exemplary) real gradient course 12 which deviates from a linear course, e.g. locally, here on the right side of its course. Such a gradient course 12 has an influence on the actual position of the slices when using the theoretical gradient value ascertained on the basis of an ideal gradient course 11. FIG. 4 shows a cross-sectional image of a part of the body 20, e.g. of an elbow, with suggested target positions 22 for a plurality of slices. These are the positions which should actually be measured. On the other hand, FIG. 5 also shows the image of a part of the body 20, the positions here being set by applying a theoretical gradient value. This results in distorted slice positions 21 compared to FIG. 4. These are shown here somewhat exaggeratedly distorted for clarity. It can be seen that in this example, the distorted slice positions 21 are shifted to the right compared to the target positions 22, e.g. in the area on the right of the image.

Such a distortion is to be prevented using the method according to the disclosure. Referring again to the method shown in FIG. 1, a frequency offset is determined for each of the parallel slices in a further step 104. The frequency offsets are based on the difference between the actual gradient value 12 and the theoretical gradient value 11. For example, the frequency offsets can be determined on the basis of ascertained distorted slice positions 21. In an embodiment, a difference between the respective target position 22 and the respective distorted slice position 21 can be formed for this purpose. According to a formula of the form f(z)=m×G_{z}×z, the frequency offset df(z) can thus be determined based on the gradient G_{z} of the ideal gradient course 11 at a position z. The respective distorted slice position 21 can, for example, be determined based on the respective actual gradient value 12 and the respective theoretical gradient value 11 of the respective slice. In an embodiment, the difference Δg_{z} between these two gradient values 11, 12 can be formed so that the frequency offset df(z) is determined by replacing the variable G_{z} with Δg_{z} in the formula f(z)=m×G_{z}×z, resulting in df(z)=m×Δg_{z}×z. Alternatively, a distorted slice position can be determined by applying the inverse of a (known) distortion correction to the target position 22. The frequency offset df(z)=m×G_{z}×dz can then be determined from the difference dz between the distorted slice position 21 and the target position 22.

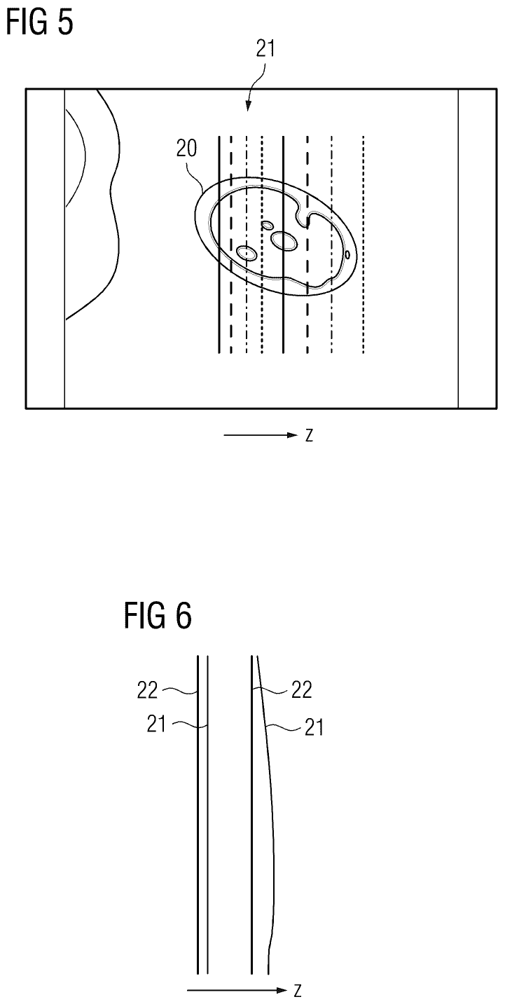

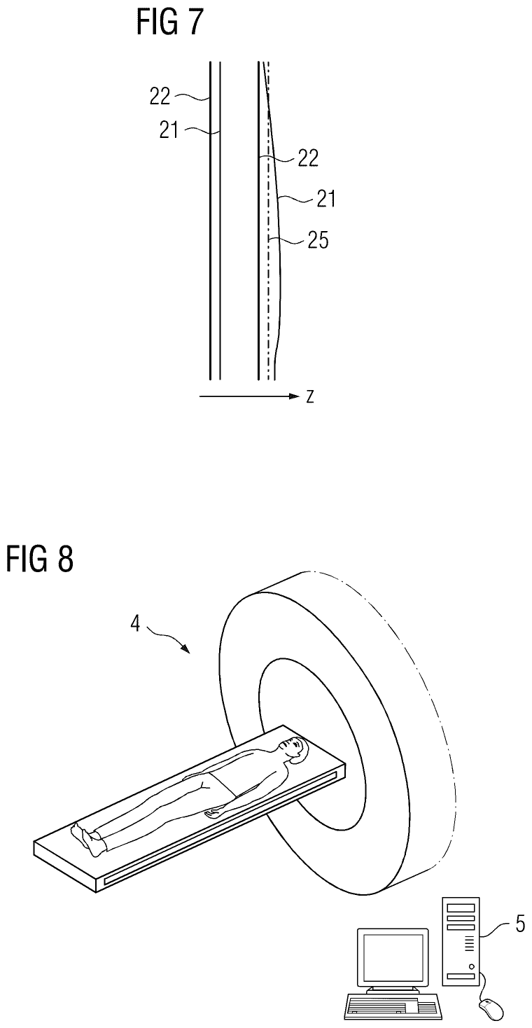

In addition to a distortion of the slice positions in the z-direction, distortion of the slices themselves can also occur. This is shown as an example in FIG. 6, where the target position 22 and the distorted slice position 21 are shown for two slices. The course of the slice itself is also shown in a direction perpendicular to the z-direction. This can result in curved slices, e.g. in edge areas of the scan area, as indicated here by the distorted slice on the right. In such a case, in order to define a distorted slice position 21, it may be provided to define a center point or a center line of the respective slice, based on which the distorted slice position 21 is defined. Alternatively, it may also be provided to use a central position of the slices to define the distorted slice position 21.

Referring again to the method shown in FIG. 1, in a further step 105, an applicable pulse frequency of an excitation pulse is determined as a superposition of individual pulses of the parallel slices. The frequency of the individual pulses is based on the frequency offset and the theoretical gradient value of the respective parallel slices. In an embodiment, an addition of the frequency offset to the frequency calculated using the theoretical gradient values may be provided in order to determine the individual pulses. The addition may also be an addition with a negative sign, i.e. a subtraction.

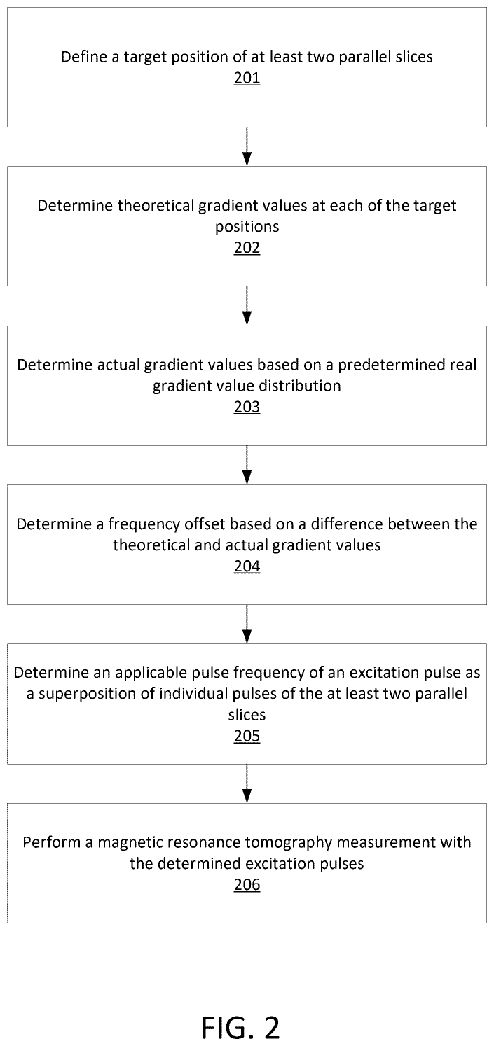

FIG. 2 illustrates a flow chart of another example method for the simultaneous recording of at least two parallel slices during a magnetic resonance tomography measurement with a magnetic resonance tomography system, according to an embodiment of the disclosure. In this example, FIG. 2 shows a flow chart of a method for the simultaneous recording of at least two parallel slices in a magnetic resonance tomography measurement with a magnetic resonance tomography system 4 according to an embodiment of the disclosure. In a first step 201, a target position 22 is defined for each of the at least two parallel slices. In a further step 202, theoretical gradient values are determined at the target positions 22 assuming an ideal, e.g. linear, local gradient profile 11. In a further step 203, actual gradient values at the target positions 22 are determined based on a predetermined, location-dependent, real gradient value distribution. In a further step 204, a frequency offset is determined for each of the parallel slices based on a difference between the actual gradient value and the theoretical gradient value. In a further step 205, a pulse frequency of an excitation pulse is determined as a superposition of individual pulses of the parallel slices. The frequency of the individual pulses is based on the frequency offset and the theoretical gradient value of the respective parallel slices. These steps 201-205 may correspond for instance to the steps 101-105 of the method described with reference to FIG. 1. In a further step 206, a magnetic resonance tomography measurement is performed with the determined excitation pulses. In an embodiment, this can be a magnetic resonance tomography measurement based on a Simultaneous Multi-Slice (SMS) method.

FIG. 8 illustrates a section of an example magnetic resonance tomography system, according to an embodiment of the disclosure. In this example, FIG. 8 shows a section of a magnetic resonance tomography system 4 according to an embodiment of the disclosure. The magnetic resonance tomography system 4 is designed to simultaneously record at least two parallel slices during a magnetic resonance tomography measurement. The magnetic resonance tomography system 4 comprises a patient examination region (which may comprise a bore-shaped region to receive the patient via a patient bench as shown) as shown and a control apparatus 5 (also referred to herein as a computer unit, a control unit, a controller, or control circuitry) which is designed to carry out any of the methods as described herein, e.g. those described with reference to FIG. 1 or FIG. 2, or to prompt the magnetic resonance tomography system 4 to carry out such a method. A corresponding computer program product may be installed on the control apparatus 5 (e.g. as computer-readable instructions stored on any suitable medium, such as a non-transitory computer-readable medium for instance) for this purpose.

The various components described herein may be referred to as “units” or “apparatuses.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such units, as applicable and relevant, may alternatively be referred to herein as “circuitry,” “controllers,” “processors,” or “processing circuitry,” or alternatively as noted herein.

What is claimed is:

1. A computer-implemented method for ascertaining excitation pulses for simultaneous recording of at least two parallel slices during a magnetic resonance tomography measurement with a magnetic resonance tomography system, the method comprising:
defining a target position for each of the at least two parallel slices;
determining theoretical gradient values at defined target positions of the at least two parallel slices assuming an ideal linear, local gradient profile;
determining actual gradient values at the defined target positions of the at least two parallel slices based on a predetermined, location-dependent real gradient value distribution;
determining a frequency offset for each of the at least two parallel slices based on a difference between the actual gradient value and the theoretical gradient value at each respective one of the defined target positions of the at least two parallel slices; and
determining a pulse frequency of an excitation pulse to be applied as a superposition of individual pulses of the at least two parallel slices,
wherein a frequency of the individual pulses is based on the frequency offset and the theoretical gradient value at the defined target positions of respective ones of at least two parallel slices.

2. The method as claimed in claim 1, wherein the frequency offsets for the at least two parallel slices are determined by:
determining a distorted slice position based on the respective actual gradient value and the respective theoretical gradient value at the defined target positions of the respective ones of the at least two parallel slices; and
determining the respective frequency offset based on the distorted slice position.

3. The method as claimed in claim 1, wherein the respective frequency offsets for the at least two parallel slices are determined by:
determining a distorted slice position based on an inverse application of a distortion correction to the target position of respective ones of the at least two parallel slices; and
determining the respective frequency offset based on the distorted slice position.

4. The method as claimed in claim 2, wherein the distorted slice positions, as viewed along a theoretical slice plane, are defined based on a center point or a center line or based on a central position of a respective one of the at least two parallel slices that is distorted according to the actual gradient value.

5. The method as claimed in claim 2, wherein the distorted slice positions, as viewed along a theoretical slice plane, are defined based on a central position of a respective one of the at least two parallel slices that is distorted according to the actual gradient value.

6. The method as claimed in claim 1, wherein respective frequency offsets for each of the at least two parallel slices are determined by:
calculating the gradient value difference between the theoretical gradient value and the actual gradient value of a respective one of the at least two parallel slices; and
determining the respective frequency offset based on the respective gradient value difference of the respective one of the at least two parallel slices.

7. The method as claimed in claim 1, wherein the frequency of the individual pulses is determined by an addition of a frequency based on the theoretical gradient value and the frequency offset at the defined target positions of each respective one of the at least two parallel slices.

8. The method as claimed in claim 1, wherein the actual gradient values at the defined target positions of the at least two parallel slices are determined based upon a gradient field map.

9. The method as claimed in claim 8, wherein the actual gradient values at the defined target positions of the at least two parallel slices are determined based upon a function including a spherical harmonic that describes the gradient field map.

10. The method as claimed in claim 1, further comprising:
performing the magnetic resonance tomography measurement with the determined excitation pulses.

11. A non-transitory computer-readable medium having instructions stored thereon that, when executed by control circuitry of a magnetic resonance tomography system, cause the magnetic resonance tomography system to:
ascertain excitation pulses for simultaneous recording of at least two parallel slices during a magnetic resonance tomography measurement with a magnetic resonance tomography system by:
defining a target position for each of the at least two parallel slices;
determining theoretical gradient values at defined target positions of the at least two parallel slices assuming an ideal linear, local gradient profile;
determining actual gradient values at the defined target positions of the at least two parallel slices based on a predetermined, location-dependent real gradient value distribution;
determining a frequency offset for each of the at least two parallel slices based on a difference between the actual gradient value and the theoretical gradient value at each respective one of the defined target positions of the at least two parallel slices; and
determining a pulse frequency of an excitation pulse to be applied as a superposition of individual pulses of the at least two parallel slices,
wherein a frequency of the individual pulses is based on the frequency offset and the theoretical gradient value at the defined target positions of respective ones of at least two parallel slices.

12. A magnetic resonance tomography system configured to simultaneously record at least two parallel slices during a magnetic resonance tomography measurement, comprising:
a patient examination region; and
control circuitry configured to cause the magnetic resonance tomography system to:
ascertain excitation pulses for simultaneous recording of at least two parallel slices during a magnetic resonance tomography measurement with a magnetic resonance tomography system by:
define a target position for each of the at least two parallel slices;
determine theoretical gradient values at defined target positions of the at least two parallel slices assuming an ideal linear, local gradient profile;
determine actual gradient values at the defined target positions of the at least two parallel slices based on a predetermined, location-dependent real gradient value distribution;
determine a frequency offset for each of the at least two parallel slices based on a difference between the actual gradient value and the theoretical gradient value at each respective one of the defined target positions of the at least two parallel slices; and
determine a pulse frequency of an excitation pulse to be applied as a superposition of individual pulses of the at least two parallel slices,
wherein a frequency of the individual pulses is based on the frequency offset and the theoretical gradient value at the defined target positions of respective ones of at least two parallel slices.
